(19) United States
(12) Patent Application Publication
(10) Pub. No.: US 2024/0353757 A1
(43) Pub. Date: Oct. 24, 2024

(54) MEASUREMENT APPARATUS AND METHOD FOR INSPECTING PHOTOMASKS INTENDED FOR EUV MICROLITHOGRAPHY

(71) Applicant: Carl Zeiss SMT GmbH, Oberkochen (DE)

(72) Inventors: Christian Roedel, Schmalkalden (DE); Senthil Lakshmanan, Erfurt (DE); Lutz Brekerbohm, Hardegsen (DE); Ulrich Matejka, Jena (DE)

(21) Appl. No.: 18/639,028

(22) Filed: Apr. 18, 2024

(30) Foreign Application Priority Data
Apr. 21, 2023 (DE) 102023110174.9

(51) Int. Cl. G03F 7/00

(52) U.S. Cl. CPC G03F 7/70033; G03F 7/70733; G03F 7/70833; G03F 7/70975; G03F 7/70983

(57) ABSTRACT

Measurement apparatus for the inspection of photomasks, comprising an EUV radiation source, an illumination system, a projection lens and an EUV image sensor. EUV radiation emitted by the EUV radiation source is guided via the illumination system to a photomask. EUV radiation reflected at the photomask is guided via the projection lens to the EUV image sensor such that the photomask is imaged on the EUV image sensor. A pellicle is arranged between the EUV radiation source and the illumination system, with the result that the EUV radiation passes through the pellicle between the EUV radiation source and the illumination system. The invention also relates to a method for inspecting photomasks.

### CROSS-REFERENCE TO RELATED APPLICATIONS

This application claims priority under 35 U.S.C. § 119 from German Application No. 10 2023 110 174.9, filed on Apr. 21, 2023, the entire contents of which are incorporated herein by reference.

### TECHNICAL FIELD

The invention relates to a measurement apparatus and to a method for inspecting photomasks intended for EUV microlithography.

### BACKGROUND

Photomasks are used in microlithographic projection exposure apparatuses, which are used to produce integrated circuits with particularly small structures. The photomask illuminated by very short-wave extreme ultraviolet radiation (EUV radiation) is imaged onto a lithography object in order to transfer the mask structure to the lithography object.

To ensure a high quality of the image generated on the lithography object, it is necessary for the photomask to be true to size and not adversely affected by contaminations. It is known practice to subject photomasks to an inspection, either prior to the operation in a microlithographic projection exposure apparatus or during an interruption of operation. To this end, a so-called aerial image of the photomask or of a portion of the photomask is generated, the photomask in the process being imaged not onto a lithography object but onto an EUV image sensor. Using the imaging onto the EUV image sensor as a basis, it is possible to make an assessment as to whether the photomask is without defects and contaminations.

The mask inspection should be performed in such a way that the measurement result is not falsified by contaminations. In particular, the photomask should be prevented from experiencing contamination as a result of the mask inspection procedure.

### SUMMARY

The invention is based on the aspect of presenting a measurement apparatus and a method for mask inspection, in which the risk of contaminations is reduced. The aspect is achieved by the features of the independent claims. Advantageous embodiments are specified in the dependent claims.

The measurement apparatus according to the invention for the inspection of photomasks comprises an EUV radiation source, an illumination system, a projection lens and an EUV image sensor. EUV radiation emitted by the EUV radiation source is guided via the illumination system to a photomask. EUV radiation reflected at the photomask is guided via the projection lens to the EUV image sensor such that the photomask is imaged onto the EUV image sensor. A pellicle is arranged between the EUV radiation source and the illumination system so that the EUV radiation passes through the pellicle between the EUV radiation source and the illumination system.

It was found that the use of measurement apparatuses for inspecting EUV photomasks entails a significant risk of the examined photomask experiencing contamination as a result of the inspection procedure. One cause of contaminations is the EUV radiation source, as particles are generated during the operation of the EUV radiation source. If these particles were to spread freely in the measurement apparatus, they could settle on the photomask. This would be particularly damaging because entire batches of semiconductor component parts which were exposed with a contaminated photomask can be unusable.

The invention proposes a pellicle arranged between the EUV radiation source and the illumination system. The pellicle prevents particles from spreading from the EUV radiation source into the illumination system. The risk of contaminations within the measurement apparatus and in particular the risk of contaminations of the photomask are reduced.

A pellicle refers to a membrane that is designed to allow EUV radiation to pass but suppresses a passage of particles. Since matter is generally highly absorptive with regards to EUV radiation, the material and the structure of the pellicle must be carefully adapted regarding use in a measurement apparatus for mask inspection. For instance, unlike in the case of visible light, it is not possible to use glass panes as a protection against contaminations. The EUV radiation would be absorbed in the glass pane and would not arrive at the image sensor with a sufficient intensity.

In an embodiment, the pellicle is a CNT (carbon nanotubes) pellicle, i.e. a membrane made of carbon nanotubes. The density and the bundle structure of the carbon nanotubes can be chosen such that, firstly, the membrane is transmissive to EUV radiation, whereas, secondly, particles are stopped at the membrane and cannot pass through the membrane. The membrane may be provided with a coating in order to provide the membrane with a sufficient resistance to radical ions and molecules. In an alternative embodiment, the pellicle comprises a membrane made of silicon, made of silicon nitride or made of any other silicon-containing material. If sufficiently thin, such membranes made of silicon material also provide sufficient transmissivity for EUV radiation.

The pellicle may be arranged such that EUV radiation emerging from the EUV radiation source passes through the pellicle before entering the illumination system. The illumination system may comprise one or more EUV mirrors, at which the EUV radiation on the path between the EUV radiation source and the photomask is reflected. The pellicle may be arranged between the EUV radiation source and the first EUV mirror of the illumination system so that the EUV radiation is not previously reflected at another EUV mirror of the illumination system. The illumination system may be configured such that a partial portion of the photomask is illuminated. The illumination system may be configured such that the intensity of the EUV radiation is substantially uniform within the illuminated partial portion.

The optical area of an EUV mirror can be formed by a highly reflective coating. The latter may be a multilayer coating, in particular a multilayer coating having alternating layers of molybdenum and silicon. Using such a coating, it is possible to reflect approximately 70% of the incident EUV radiation. The term EUV radiation is used to refer to electromagnetic radiation in the extreme ultraviolet spectral range with wavelengths of between 5 nm and 100 nm, in particular with wavelengths of between 5 nm and 30 nm.

The projection lens of the measurement apparatus may comprise a plurality of EUV mirrors, at which the EUV radiation between the photomask and the image sensor is reflected. The projection lens may comprise a first mirror M1, which captures EUV radiation reflected by the photomask. The EUV radiation reflected at the first mirror M1 can be guided to the EUV image sensor via one or more further mirrors of the projection lens. In particular, the EUV radiation can be guided to the image sensor such that an image of the photomask, in particular of a portion of the photomask, is created on the image sensor. The portion of the photomask imaged onto the image sensor may correspond to a small partial portion of the photomask.

The measurement apparatus may comprise a vacuum chamber in which a vacuum is present during the measurement. The projection lens, the illumination system and/or the EUV radiation source may be arranged in the vacuum chamber. In the vacuum chamber a subchamber may be formed, which is separated from other regions of the vacuum chamber by an intermediate housing. The EUV radiation source may be arranged in the subchamber.

The intermediate housing may be provided with pressure equalization channels, by means of which pressure is equalized between the subchamber and the rest of the vacuum chamber. There is not necessarily complete pressure equalization between the subchamber and the rest of the vacuum chamber. For example, a purge gas can be introduced into the subchamber in order to remove contaminations generated by the EUV radiation source. This may cause the total pressure or a partial pressure and/or the gas composition within the subchamber to be different from the rest of the vacuum chamber.

The subchamber may have an exit opening through which EUV radiation emitted by the EUV radiation source passes in the direction of the illumination system. The exit opening may be covered by the pellicle, with the result that all the EUV radiation exiting from the subchamber through the exit opening goes through the pellicle, i.e. passes through the pellicle. The pellicle can be sealingly flush with a housing periphery surrounding the opening, with the result that a transfer of particles between the subchamber and the rest of the vacuum chamber at the transition between the pellicle and the housing or between a frame of the pellicle and the housing is prevented. The pellicle can be designed so as to withstand a pressure difference that may be present above the pellicle during operation of the measurement apparatus.

The pellicle may be mounted on a frame. The pellicle may be fastened to the frame in such a way that an opening spanned by the frame is covered by the pellicle. The connection to the partial housing of the vacuum chamber can be made via the frame. The connection between the frame and the carrying structure of the measurement apparatus, in particular the connection between the frame and the partial housing of the vacuum chamber, may be a releasable connection to allow for replacement of the pellicle. The pellicle may need to be replaced if the latter has become contaminated after being used for a certain amount of time. The pellicle may be a consumable designed for regular replacement within the scope of servicing measures. The replacement of the pellicle can be undertaken manually. A motor-driven mechanism for the replacement of the pellicle is also possible.

The measurement apparatus may be equipped with a holding device which carries a plurality of pellicles. Each of the pellicles can be suspended on a frame. The holding device may have a uniform frame component part having a plurality of pellicles or comprise a plurality of frame component parts. The measurement apparatus may be configured such that the EUV radiation passes through a first pellicle in a first state of the holding device and the EUV radiation passes through a second pellicle in a second state of the holding device. The holding device may have more than two pellicles and more than two associated states. The holding device may comprise, for example, a turret unit in which the change between the pellicles is effected by a rotary movement. The measurement apparatus may comprise a motorized drive to switch between the states of the holding device. The measurement apparatus may comprise a control unit to control the holding device.

By providing a plurality of pellicles that can be arranged in front of the EUV radiation source, the maintenance complexity can be reduced. In a measurement apparatus having a single pellicle in front of the EUV radiation source, the maintenance intervals depend on how long it takes for the individual pellicle to be used up. If there are a plurality of pellicles, the maintenance intervals are extended according to the number of pellicles. Once a pellicle is used up, the holding device is simply actuated to insert the next pellicle into the EUV beam path.

The measurement apparatus may comprise a loading mechanism intended to remove the pellicle from the vacuum chamber of the measurement apparatus and replace it with a new pellicle. The pellicle can be replaced together with the frame. The loading mechanism may be designed to replace a plurality of particles in one replacement operation. The replacement operation can be performed as an automatic process, without manual intervention.

To replace the pellicle, the vacuum in the vacuum chamber can be dissolved so that ambient pressure is present in the vacuum chamber. An opening in the housing of the vacuum chamber can then be opened, through which the vacuum chamber can be accessed in order to remove and replace the pellicle.

Embodiments in which the measurement apparatus comprises an airlock through which the replacement of the pellicle takes place are also possible. The same pressure can be present in both an airlock chamber and the vacuum chamber in a first state of the airlock, with the result that the photomask can be conveyed without pressure difference between the airlock chamber and the vacuum chamber. In a second state of the airlock, a pressure higher than the vacuum pressure and corresponding to the pressure in the surroundings of the airlock may be present in the airlock chamber. The pressure in the second state of the airlock corresponds to atmospheric pressure in one embodiment. In the second state of the airlock, the photomask can be conveyed without pressure difference between the airlock chamber and the surroundings of the airlock.

It is possible that the measurement apparatus according to the invention comprises further pellicles, which are arranged in one or more other sections of the EUV beam path, with the result that the EUV radiation successively passes through a plurality of pellicles. This may comprise further pellicles through which the EUV radiation passes exactly once. In addition or as an alternative, this may comprise pellicles which are arranged such that the EUV radiation passes through the pellicle twice.

The measurement apparatus may comprise a spectral filter arranged between the EUV radiation source and the photomask for influencing the spectral composition of the EUV radiation. For the inspection of the photomask, it is advantageous if the EUV radiation comprises only electromagnetic radiation in a narrow wavelength range around 13.5 nm. If longer-wave electromagnetic radiation is also emitted by the EUV radiation source, for example in the EUV wavelength range, in the visible wavelength range or in the infrared wavelength range, these components interfere with the measurement. The filter can be designed as a bandpass filter. The passband of the band filter can be between 10 nm and 20 nm, preferably between 11 nm and 15 nm. Spectral components outside the passband, in particular longer-wave spectral components, are significantly attenuated.

In one embodiment, the spectral filter is a Zr filter, in which the EUV radiation passes through a thin layer of zirconium. The Zr filter can comprise a frame over which a zirconium foil is clamped. Zirconium has suitable transmission properties and absorption properties for this purpose. However, thin zirconium layers are not very mechanically resistant. The Zr filter can therefore comprise a grid made of a mechanically more resistant material on which the zirconium layer is supported. The grid can be a wire mesh, for example made of metal wires.

Such a reinforcing structure of the Zr filter has an additional absorbing effect on the EUV radiation, so that the transmittance of the Zr filter decreases. In one embodiment, the Zr filter is free of a reinforcing structure. Such a Zr filter is preferably arranged in a region of the measurement apparatus in which the zirconium layer is not exposed to large loads.

The spectral filter can be arranged between the pellicle and the photomask. If the pellicle lies between the EUV radiation source and the spectral filter, it is ensured that the spectral filter is not damaged by particles emitted by the EUV radiation source, as the particles are prevented by the pellicle from moving towards the spectral filter. It is advantageous if the spectral filter is located at a distance from the pellicle. For example, at least one EUV mirror of the illumination system may be arranged between the spectral filter and the pellicle.

In one embodiment, the spectral filter is designed to form a structural unit with the pellicle. For example, a frame that holds a pellicle can hold the spectral filter at the same time, with the result that the EUV radiation passes through the pellicle and through the spectral filter. The spectral filter may be formed as a foil which extends parallel to the pellicle.

It is also possible that the spectral filter is in a direct two-dimensional connection with the pellicle. For example, the spectral filter can be applied as a thin layer of zirconium directly to the pellicle, so that the modified pellicle combines a mechanical filter effect and a spectral filter effect. The layer of zirconium may be applied to the side of the pellicle facing the EUV radiation source, applied to the side of the pellicle facing away from the EUV radiation source, or applied to both sides of the pellicle. With such a uniform design of the pellicle and spectral filter, the spectral filter can be a consumable that is subject to the same maintenance interval as the pellicle. The replacement of the consumable can take place in the same way as described in the context of the unmodified pellicle A spectral filter which is realized as a structural unit separate from the pellicle usually has a longer operating life than a pellicle.

The invention also relates to a method for inspecting photomasks, in which EUV radiation emitted by an EUV radiation source is guided via an illumination system to a photomask. EUV radiation reflected at the photomask is guided via a projection lens to an EUV image sensor such that the photomask is imaged onto the image sensor. The EUV radiation passes through a pellicle which is arranged between the EUV radiation source and the illumination system.

The disclosure encompasses developments of the method with features which are described in the context of the measurement apparatus according to the invention. The disclosure encompasses developments of the measurement apparatus with features that are described in the context of the method according to the invention.

### BRIEF DESCRIPTION OF DRAWINGS

The invention will be described by way of example below on the basis of advantageous embodiments by reference to the accompanying drawings. In the figures:

FIG. 1: shows a schematic illustration of a measurement apparatus according to the invention;

FIG. 2: shows the pellicle unit of the measurement apparatus from FIG. 1;

FIG. 3: shows a schematic illustration of a photomask;

FIG. 4: shows details from FIG. 1 in the case of an alternative embodiment of the invention;

FIG. 5: shows components of the measurement apparatus from FIG. 4;

FIG. 6: shows the view according to FIG. 5 in an alternative embodiment of the invention;

FIGS. 7, 8: show the view according to FIG. 4 in the case of alternative embodiments of the invention;

FIGS. 9, 10: show the view according to FIG. 2 in alternative embodiments of the invention.

### DETAILED DESCRIPTION

Microlithographic photomasks 17 can be examined using a measurement apparatus according to the invention.

In general, microlithographic photomasks 17 are provided for use in a microlithographic projection exposure apparatus (not depicted). In the microlithographic projection exposure apparatus, the photomask 17 is illuminated with extreme ultraviolet radiation (EUV radiation) at a wavelength of for example 13.5 nm in order to image a structure formed on the photomask 17 onto the surface of a lithographic object in the form of a wafer. The wafer is coated with a photoresist that reacts to the EUV radiation. The measurement apparatus is used to examine whether the measurement apparatus meets the specifications and is free from contaminations.

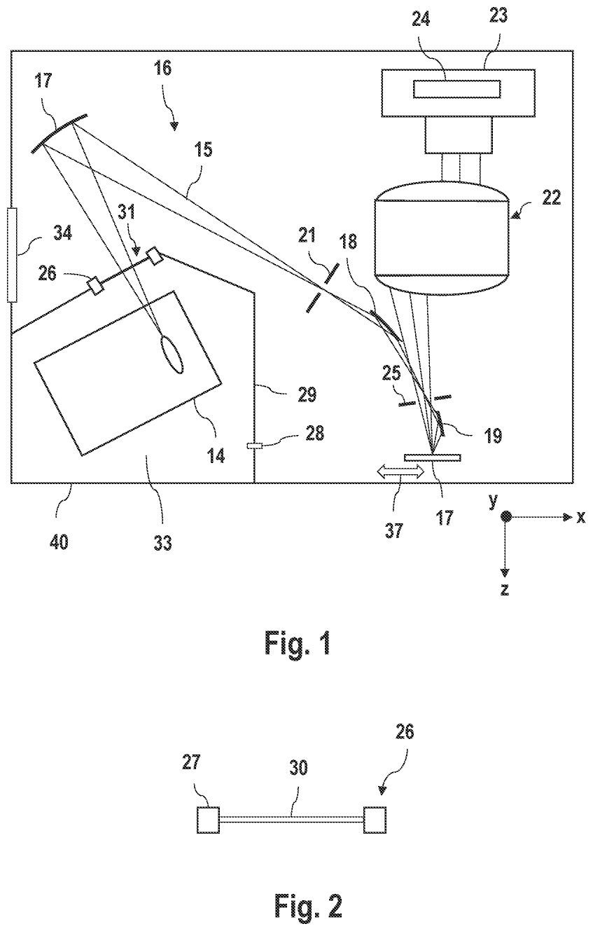

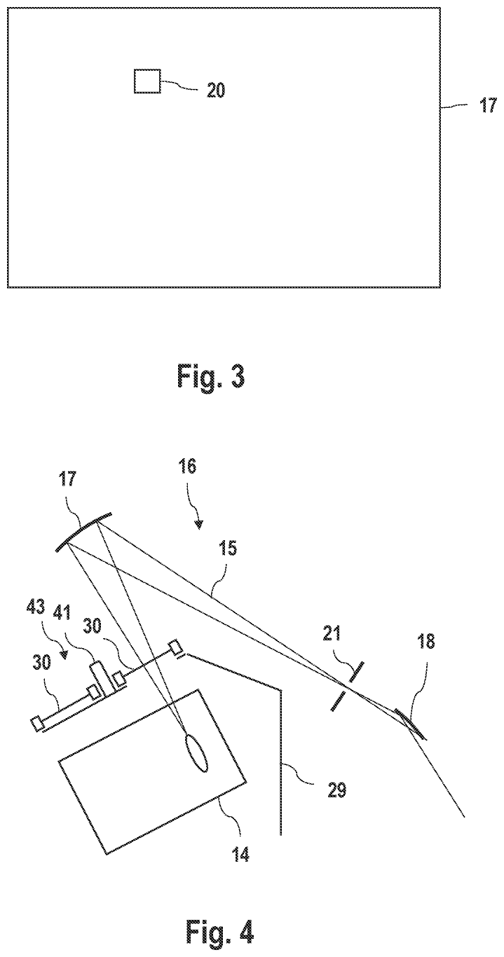

According to FIG. 1, the photomask 17 is arranged in the measurement apparatus such that an EUV beam path 15 emanating from an EUV radiation source 14 is guided via an illumination system 16 to the photomask 17. The illumination system 16 comprises a first illumination mirror 17, a second illumination mirror 18 and a third illumination mirror 19 at which the EUV beam path 16 is reflected and shaped into a beam with which an examination field 20 on the surface of the photomask 17 is lit with uniform brightness. The examination field 20, which is small in comparison with the area of the photomask 17, is illustrated in FIG. 3 in an illustration that is not true to scale. For example, the lit region 20 may have dimensions of 0.5 mm×0.8 mm. The edge lengths of the photomask 17 can be between 100 mm and 200 mm, for example. A field stop 21 used to delimit the lit region to the examination field 20 on the surface of the photomask 17 is arranged between the first illumination mirror 17 and the second illumination mirror 18. Using an XY-positioning mechanism 37, it is possible to move the photomask in the XY-plane in order to bring different examination fields 20 into the region of the EUV beam path.

The EUV beam path 15 reflected at the photomask 17 continues through a projection lens 22 to an EUV camera 23, which is equipped with an image sensor 24, which can be, e.g., a charge coupled device (CCD) sensor, a complementary metal oxide semiconductor (CMOS) sensor, or a time delay and integration (TDI) sensor. The projection lens 22 can include one or more mirrors at which the EUV radiation is reflected and via which the examination field 20 of the photomask 17 is imaged onto the image sensor 24 of the EUV camera 23. An aperture stop 25 whose aperture corresponds to the first mirror M1 is arranged between the photomask 17 and the first mirror M1. The EUV radiation source 14, the illumination system 15, the photomask 17, the projection lens 22 and the EUV camera 23 are arranged in a vacuum housing 40, in which a negative pressure prevails during the operation of the measurement apparatus.

The EUV radiation source 14 is a plasma radiation source, in which the EUV radiation is emitted from a plasma at a wavelength of 13 nm. Tin is a medium that can be used to generate a plasma suitable for emitting such EUV radiation. A laser beam can be made to impinge on a droplet of the medium for the purpose of generating the plasma.

The mirrors in the illumination system 16 and the mirrors in the projection lens 22 are designed as EUV mirrors which have a particularly high reflectivity for EUV radiation. The optical area of the EUV mirrors can be formed by a highly reflective coating. The latter may be a multilayer coating, in particular a multilayer coating having alternating layers of molybdenum and silicon. Using such a coating, it is possible to reflect approximately 70% of the incident EUV radiation.

The projection lens 22 has a magnification factor of more than 100. In order to be able to record the entirety of the picture generated by the examination field 20 of the photomask 17, the area of the image sensor 24 is greater than the area of the examination field 20 in accordance with the magnification factor. For example, the image sensor 24 may have dimensions in the order of magnitude of 100 mm to 200 mm.

Within the vacuum housing 40, a subchamber 33 is formed, which is separated by an intermediate housing 29 from the other regions in the interior of the vacuum housing 40. In the intermediate housing 29, pressure equalization channels 28 are formed, via which a pressure equalization between the subchamber 33 and other regions in the interior of the vacuum housing 40 arises. The subchamber 33 is treated with a purge gas to remove contaminations, with the result that the composition of the gas and the pressure in the subchamber 33 do not necessarily match the conditions in other regions.

The EUV radiation source 14 is arranged in the subchamber 33. In the intermediate housing 29, an exit opening 31 is formed through which EUV radiation emitted by the EUV radiation source 14 exits from the subchamber 33 in the direction of the illumination system 16. A housing periphery of the intermediate housing 29 surrounds the exit opening 31 in a circular manner. A pellicle unit 26 is connected to the housing periphery. According to FIG. 2, the pellicle unit 26 comprises a frame component part 27 in which a pellicle 30 is clamped. The frame component part 27 of the pellicle unit 26 is mounted on the intermediate housing 29 of the measurement apparatus by use of a screw connection.

The pellicle 30 is a very thin membrane made of a carbon nanotube material which allows good passage of EUV radiation but obstructs the passage of particles. The illumination system 16 is protected by the pellicle 30 from particulate contaminations. Particles forming in the EUV radiation source 14, which move in the direction of the illumination system 16, are incident and deposit on the pellicle 30.

The frame component part 27 of the pellicle unit 26 can be detached from the intermediate housing 29 during a maintenance operation in order to replace the used-up pellicle 30 with a new pellicle. For this purpose, the vacuum in the vacuum housing 40 is dissolved so that ambient pressure is present in the interior of the vacuum housing 40. A housing opening 34 is opened so that manual access to the interior of the vacuum housing 40 becomes possible. The screw connection between the frame component part 27 and the intermediate housing 29 is removed so that the pellicle unit 26 can be removed from the vacuum housing 40. The new pellicle 30 can be inserted with a new frame component part 27 into the measurement apparatus and connected to the intermediate housing 29.

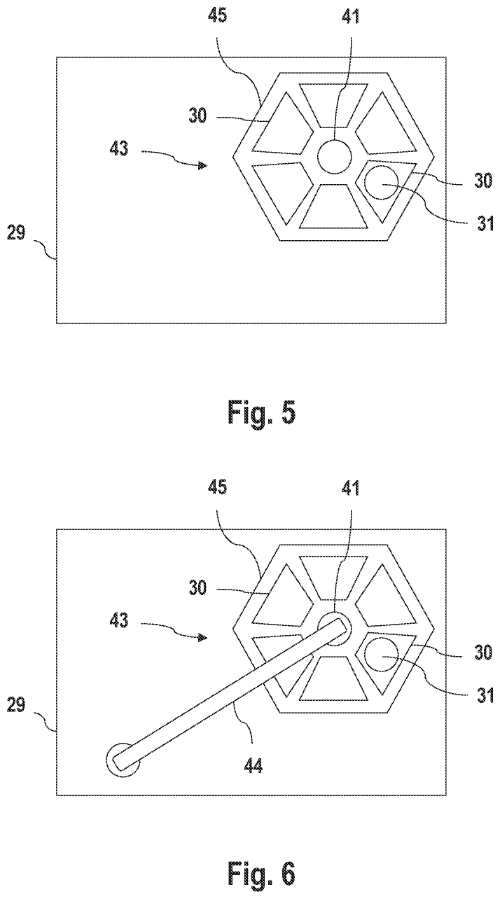

In the embodiment according to FIGS. 4 and 5, the measurement apparatus is equipped with a holding device 43, which comprises a frame component part 45, in which a plurality of pellicles 30 are held. The frame component part 45 is mounted on a rotary drive 41 so that the frame component part 45 can be rotated about a central axis. Depending on the rotational position of the frame component part 45, other pellicles 30 are arranged in front of the exit opening 31 in the intermediate housing 29. In the exemplary embodiment shown, the frame component part 45 carries six pellicles 30, which means that the measurement apparatus can remain in operation six times as long before the pellicles 30 must be replaced as part of a maintenance operation.

In FIGS. 4 and 5, the replacement of the frame component part 45 with the pellicles 30 is carried out manually by opening the housing opening 34 and replacing the frame component part 45 with a new frame component part with new pellicles. In the alternative embodiment according to FIG. 6, the frame component part 45 is suspended on a swivel mechanism 44. With the swivel mechanism 44, the frame component part 45 can be transferred into an airlock chamber, with the result that the frame component part 45 with the pellicles 30 can be replaced without the vacuum in the vacuum housing 40 needing to be dissolved.

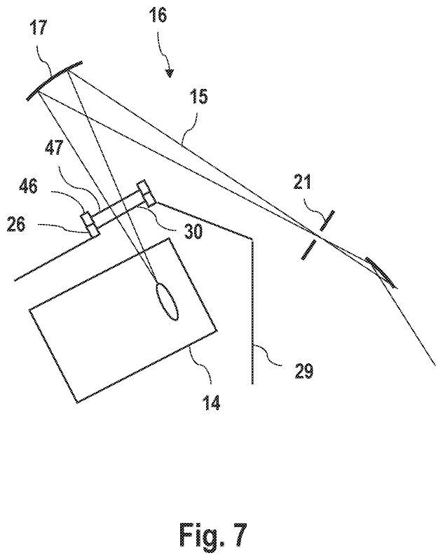

In the alternative embodiment according to FIG. 7, a further frame part 46, in which a foil of a zirconium material is clamped, is connected to the frame component part 27 of the pellicle unit 26. The foil of the zirconium material forms a spectral filter 47, which has a high transmittance at 13.5 nm and which strongly attenuates other wavelengths of electromagnetic rays, in particular longer-wave spectral range into the infrared range. The spectral filter 47 is protected from incident particles by the pellicle 30 and thus has a longer service life. The foil of the zirconium material is supported by a metal grid integrally connected to the foil so that the spectral filter 47 has sufficient resistance to the ambient conditions prevailing in the vicinity of the EUV radiation source 14.

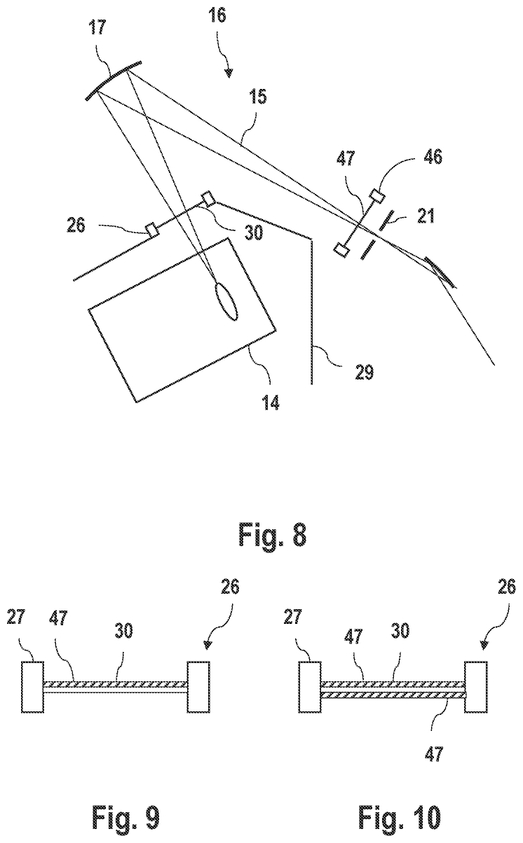

FIG. 8 shows a variant in which the spectral filter 47 is arranged at a greater distance from the EUV radiation source 14, to be precise near the field stop 21. Here, the operating conditions are more favourable, so that a pure zirconium foil without supporting grid can be clamped in the frame part 46. The loss of intensity of the EUV radiation caused by the spectral filter 47 is less than in FIG. 7.

FIG. 9 shows an embodiment in which the pellicle 30 itself is provided with a coating of a zirconium material. The zirconium layer forms the spectral filter 47 for the EUV radiation. In FIG. 9, the zirconium layer is applied to the outside of the pellicle, i.e. to the side facing the illumination system 16 and the side of the pellicle 30 facing away from the EUV radiation source 14. In FIG. 10, the pellicle 30 is provided with a zirconium layer both on its outside and on its inside. The spectral filtering effect is increased in this way, but the zirconium layer on the inside degrades faster because it is exposed to the particles emitted by the EUV radiation source 14. In the embodiments of FIGS. 9 and 10, the spectral filter 47 is consumable material, which is replaced together with the pellicle 30.

Although the present invention has been described with reference to exemplary embodiments, it is modifiable in various ways.

What is claimed is:

1. A measurement apparatus for the inspection of photomasks, comprising an EUV radiation source, an illumination system, a projection lens and an EUV image sensor, wherein EUV radiation emitted by the EUV radiation source is guided via the illumination system to a photomask, wherein EUV radiation reflected at the photomask is guided via the projection lens to the EUV image sensor with the result that the photomask is imaged onto the EUV image sensor, and wherein a pellicle is arranged between the EUV radiation source and the illumination system such that the EUV radiation passes through the pellicle between the EUV radiation source and the illumination system.

2. The measurement apparatus of claim 1, wherein the pellicle is arranged between the EUV radiation source and a first mirror of the illumination system.

3. The measurement apparatus of claim 1, comprising a vacuum chamber in which the projection lens, the illumination system and/or the EUV radiation source are arranged.

4. The measurement apparatus of claim 3, wherein the EUV radiation source is arranged in a subchamber of the vacuum chamber.

5. The measurement apparatus of claim 4, wherein the subchamber has an exit opening and wherein the exit opening is covered by the pellicle.

6. The measurement apparatus of claim 5, wherein the pellicle is sealingly flush with a housing periphery surrounding the exit opening.

7. The measurement apparatus of claim 1, wherein the pellicle is suspended on a frame and wherein the frame is detachably connected to a carrying structure of the measurement apparatus.

8. The measurement apparatus of claim 1, comprising a holding device, which carries a plurality of pellicles, wherein the EUV radiation passes through a first pellicle in a first state of the holding device and wherein the EUV radiation passes through a second pellicle in a second state of the holding device.

9. The measurement apparatus of claim 1, comprising a loading mechanism to remove the pellicle from the vacuum chamber.

10. The measurement apparatus of claim 1, comprising a spectral filter arranged between the EUV radiation source and the photomask.

11. The measurement apparatus of claim 10, wherein the spectral filter is arranged between the pellicle and the photomask.

12. The measurement apparatus of claim 10, wherein the spectral filter is arranged between a mirror of the illumination system and the photomask.

13. The measurement apparatus of claim 10, wherein the spectral filter is applied as a coating to the pellicle.

14. A method for inspecting photomasks, wherein EUV radiation emitted by an EUV radiation source is guided via an illumination system to a photomask and wherein EUV radiation reflected at the photomask is guided via a projection lens to an EUV image sensor such that the photomask is imaged onto the image sensor and wherein the EUV radiation passes through a pellicle arranged between the EUV radiation source and the illumination system.

15. The method of claim 14, comprising arranging the pellicle between the EUV radiation source and a first mirror of the illumination system.

16. The method of claim 14, comprising arranging the projection lens, the illumination system and/or the EUV radiation source in a vacuum chamber.

17. The method of claim 16, comprising arranging the EUV radiation source in a subchamber of the vacuum chamber.

18. The method of claim 17, comprising covering, using the pellicle, an exit opening of the subchamber.

19. The method of claim 14, comprising suspending the pellicle on a frame, and detachably connecting the frame to a carrying structure of the measurement apparatus.

20. The method of claim 14, comprising arranging a spectral filter between the EUV radiation source and the photomask.
